(19) United States
(12) Patent Application Publication
(10) Pub. No.: US 2025/0221295 A1
(43) Pub. Date: Jul. 3, 2025

(54) FILM, PREPARATION METHOD THEREOF AND PHOTOELECTRIC DEVICE

(71) Applicant: TCL Technology Group Corporation, Huizhou (CN)

(72) Inventor: Qiang LUO, Huizhou (CN)

(73) Assignee: TCL Technology Group Corporation, Huizhou (CN)

(21) Appl. No.: 19/002,658

(22) Filed: Dec. 26, 2024

(30) Foreign Application Priority Data
Dec. 29, 2023 (CN) 202311842604.6

(51) Int. Cl. H10K 85/10; H10K 50/115; H10K 50/15

(52) U.S. Cl. CPC H10K 85/151; H10K 50/115; H10K 50/15

(57) ABSTRACT

The present disclosure film, preparation method thereof and photoelectric device. A film, a material of the film includes a semiconductor material and a fluorine-containing ester compound. The film provided by the present disclosure has good water-oxygen corrosion resistance and high stability.

This application claims priority to Chinese Application No. 202311842604.6, entitle.

“FILM, PREPARATION METHOD THEREOF, PHOTOELECTRIC DEVICE AND DISPLAY DEVICE”, filed on Dec. 29, 2023. The entire disclosures of the above application are incorporated herein by reference.

### TECHNICAL FIELD

The present disclosure relates to a field of display technologies, and more particularly, to film, preparation method thereof and photoelectric device.

### BACKGROUND

Semiconductor functional films are vulnerable to water-oxygen corrosion and need to be further improved.

### Technical Solution

In view of this, the present disclosure provides a film, a preparation method thereof and a photoelectric device.

The present disclosure provides a film. A material of the film includes a semiconductor material and a fluorine-containing ester compound.

The present disclosure provides a preparation method of a film, including: providing a mixed solution, the mixed solution includes a semiconductor material and a fluorine-containing ester compound; and deposing the mixed solution to obtain the film.

The present disclosure provides a photoelectric device, including: a first electrode; an active layer, located on the first electrode; a second electrode, located on the active layer; and a first carrier functional layer, between the first electrode and the active layer, and a material of the first carrier functional layer includes a semiconductor material and a fluorine-containing ester compound.

The film provided by the present disclosure has good water-oxygen corrosion resistance and high stability.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of the structure of a film according to an embodiment of the present disclosure.

FIG. 2 is a flowchart of a method for preparing a film according to an embodiment of the present disclosure.

FIG. 3 is a schematic diagram of the structure of a photoelectric device according to an embodiment of the present disclosure.

FIG. 4 is a schematic diagram of the structure of a photoelectric device according to another embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. The description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Functional layer in photoelectric device has poor tolerance to water. In the presence of water, excitons in the luminescent layer will be quenched rapidly, and the performance of photoelectric devices will drop sharply or even die directly, which will seriously affect the luminous efficiency and life of photoelectric device and aggravate the attenuation of device performance. When the carrier functional layer is exposed to water, the film will lose its carrier transport ability after annealing. This is because water will react with carrier functional materials at high temperature to generate substances without carrier transport ability, such as ZnO reacting with water to generate Zn(OH)₂, and Zn(OH)₂ has no electron transport ability.

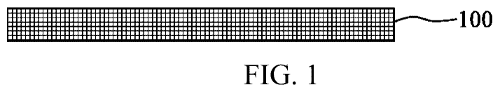

Referring to FIG. 1, the present disclosure discloses a film 100, a material of the film 100 includes a semiconductor material and a fluorine-containing ester compound.

In the film 100 provided by this present disclosure, the fluorine-containing ester compound might effectively fill the gaps of the film 100, increase the compactness of the film 100, reduce leakage current and prevent water from passing through. And the fluorine in the fluorine-containing ester compound and the ester itself are hydrophobic, so that the water-oxygen corrosion resistance of the film 100 might be further improved. The fluorine element in fluorine-containing ester compound has low electronegativity and low polarizability, resulting in strong polarity of C—F bonds. The shared electron pair of fluorocarbon atoms is greatly biased towards fluorine atoms, which makes fluorine atoms have redundant negative charges and forms a layer of negative charge protection, which prevents negatively charged nucleophiles from approaching carbon atoms for chemical reactions and prevents water and oxygen corrosion. Moreover, the bond energy of C—F bond is large, and fluorine atoms are spirally distributed along the carbon chain, which has shielding effect, low molecular force and low surface energy, and might further improve the stability of the film 100.

In some embodiments, the fluorine-containing ester compound includes one or more of fluorine-containing amino ester compound, fluorine-containing acid ester compound and fluorine-containing hydrocarbon ester compound.

In some embodiments, the fluorine-containing amino ester compound includes fluorinated polyurethane.

In some embodiments, the fluorine-containing acid ester compound includes one or more of fluorinated acrylate, and fluorinated cyanate ester.

In some embodiments, the fluorine-containing hydrocarbon ester compound includes one or more of fluorine-containing vinyl ester compound.

In some embodiments, in the film 100, a mass ratio of the semiconductor material to the fluorine-containing ester compound is (45-95):(5-30), such as 50:25, 50:30, 60:20, 60:30, 70:20, 70:30, 80:10, 80:20, 90:5, etc. Within the mass ratio range, the fluorine-containing ester compound might effectively improve the water-oxygen corrosion resistance of the film 100 without affecting the conductivity of the semiconductor material.

In some embodiments, the semiconductor material includes one or more of p-type semiconductor material and n-type semiconductor material.

In some embodiments, the p-type semiconductor material is selected from one or more of 4,4′-N,N′-dicarbazolyl-biphenyl, N,N′-diphenyl-N,N′-bis(1-naphthyl)-1, l′-biphenyl)-4,4 ‘-diamine, N,N’-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4,4′,4′-tris(carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris(N-3-methylphenyl-N-phenylamino)triphenylamine, poly[(9,9′-dioctyl fluorene-2,7-diyl)-co-(4,4′-(N-(4-sec-butylphenyl)diphenylamine))], poly(4-butylphenyl-diphenylamine), poly[bis(4-phenyl) (4-butylphenyl)amine], polyaniline, polypyrrole, poly(p)phenylene vinylene, poly(phenylene vinylene), poly[2-methoxy-5-(2-ethylhexyloxy)-1,4-phenylene vinylene], poly[2-methoxy-5-(3′,7′-dimethyl octyloxy)-1,4-phenylene vinylene], copper phthalocyanine, aromatic tertiary amine, 4,4′-bis(p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly(N-vinylcarbazole) and its derivatives, polymethacrylate and its derivatives, poly(9,9-octylfluorene) and its derivatives, poly(spirofluorene) and its derivatives, N,N′-bis(naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

In some embodiments, the n-type semiconductor material is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅⁺ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, the film includes at least two film layers, and a mass fraction of the dopant in each film layer tends to increase or decrease in the same direction. In other words, the mass fraction of dopant in any adjacent film layer increases in the same direction in turn, forming gradient doping, which makes the energy level of the film layer change gradient and is beneficial to hole transport.

In some embodiments, a surface of the semiconductor material is connected with a first hydrophobic ligand. The first hydrophobic ligand might block the corrosion of semiconductor materials by water.

In some embodiments, the first hydrophobic ligand includes substituted or unsubstituted hydrocarbon group.

In some embodiments, the hydrocarbon group includes one or more of chain hydrocarbon group and cyclic hydrocarbon group. The hydrocarbyl group includes one or more of alkyl group with 1-20 carbon atoms in the main chain, alkenyl group with 1-20 carbon atoms in the main chain and alkynyl group with 1-20 carbon atoms in the main chain. The cyclic hydrocarbon group includes one or more of aryl with 6-20 ring atoms and heteroaryl with 5-20 ring atoms.

In some embodiments, a substituent of the hydrocarbon group includes one or more of aryl, ester, ether, amine, amide and halogen.

In some embodiments, the first hydrophobic ligand is selected from one or more of methane, carbon tetrachloride, ethylene, polyvinyl fluoride and benzene.

In some embodiments, in the film 100, a mass ratio of the semiconductor material to the first hydrophobic ligand is (45-95):(1-20), such as 50:10, 50:15, 60:5, 60:10, 70:5, 70:10, 80:5, 80:10, etc. Within the mass ratio range, the first hydrophobic ligand might effectively prevent water from corroding semiconductor material.

In some embodiments, the material of the film 100 further includes a conductivity enhancer. It could be understood that the fluorine-containing ester compound has no conductivity, and the conductivity of the film 100 might be improved by adding the conductivity enhancer.

In some embodiments, a conductivity of the conductivity enhancer ranges between 100S/m-500S/m, such as 150S/m, 200S/m, 250S/m, 300S/m, 350S/m, 400S/m, 450S/m, etc. Within the conductivity range, it is beneficial for the conductivity enhancer to effectively improve the conductivity of the film 100.

In some embodiments, the conductivity enhancer is selected from one or more of carbon material and metal material.

The carbon material is selected from one or more of carbon black, conductive graphite, cochin black and carbon nanotube.

The metal material is selected from one or more of Au, Cu, Ag, Al and Fe.

In some embodiments, in the film 100, a mass ratio of the semiconductor material to the conductivity enhancer is (45-95):(1-5), such as 60:2, 70:3, 80:4, 90:1, etc. Within the mass ratio range, the conductivity enhancer might improve the conductivity of the film 100 without affecting the water-oxygen corrosion resistance of the fluorine-containing ester compound and the carrier migration performance of the semiconductor material.

In some embodiments, the material of the film 100 is composed of the semiconductor material and the fluorine-containing ester compound.

In other embodiments, the material of the film 100 is composed of the semiconductor material, the fluorine-containing ester compound and the conductivity enhancer.

In other embodiments, the material of the film 100 is composed of the semiconductor material, the fluorine-containing ester compound and the first hydrophobic ligand.

In other embodiments, the material of the film 100 is composed of the semiconductor material, the fluorine-containing ester compound, the conductivity enhancer and the first hydrophobic ligand.

In some embodiments, in the film 100, the fluorine-containing ester compound has a three-dimensional network cross-linked structure, and the semiconductor material is filled in the three-dimensional network cross-linked structure.

In some embodiments, a thickness of the film 100 ranges between 30 nm-50 nm, such as 32 nm, 35 nm, 38 nm, 40 nm, 42 nm, 45 nm, 48 nm, etc.

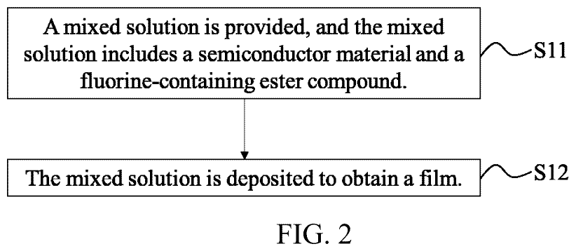

Referring to FIG. 2, the present disclosure proposes a preparation method of a film 100 which includes step S11-S12.

In step S11, a mixed solution is provided, and the mixed solution includes a semiconductor material and a fluorine-containing ester compound.

In step S12, the mixed solution is deposited to obtain a film 100.

In some embodiments, a mass concentration of the semiconductor material in the mixed solution ranges between 10 mg/mL-30 mg/mL, such as 12 mg/mL, 15 mg/mL, 18 mg/mL, 20 mg/mL, 22 mg/mL, 25 mg/mL, 28 mg/mL, etc. Within the mass concentration range, it is beneficial to the uniform dispersion of the semiconductor material.

In some embodiments, in the mixed solution, a mass ratio of the semiconductor material to the fluorine-containing ester compound is (45-95):(5-30), such as 50:25, 50:30, 60:20, 60:30, 70:20, 70:30, 80:10, 80:20, 90:5, etc. Within the mass ratio range, the fluorine-containing ester compound might effectively improve the water-oxygen corrosion resistance of the film 100 without affecting the conductivity of the semiconductor material.

In some embodiments, the mixed solution further includes a solvent. The solvent includes an alcohol solvent, and the alcohol solvent is selected from one or more of 3-methoxybutan-1-ol, methanol, ethanol, propanol, butanol, ethylene glycol, isopropanol, glycerol and cresol.

In some embodiments, the mixed solution further includes a first hydrophobic ligand. It could be understood that the first hydrophobic ligand might be connected to the surface of the semiconductor material in the mixed solution to prevent the corrosion of the semiconductor material by water.

In some embodiments, in the mixed solution, a mass ratio of the semiconductor material to the first hydrophobic ligand is (45-95):(1-20), such as 50:10, 50:15, 60:5, 60:10, 70:5, 70:10, 80:5, 80:10, etc. Within the mass ratio range, the first hydrophobic ligand might improve the conductivity of the film 100 without affecting the water-oxygen corrosion resistance of the fluorine-containing ester compound and the carrier migration performance of the semiconductor material.

In some embodiments, the mixed solution further includes a conductivity enhancer.

In some embodiments, in the mixed solution, a mass ratio of the semiconductor material to the conductivity enhancer is (45-95):(1-5), such as 60:2, 70:3, 80:4, 90:1, etc. Within the mass ratio range, the conductivity enhancer might effectively block the corrosion of semiconductor materials by water.

In some embodiments, after disposing the mixed solution, the method further includes thermal annealing.

In some embodiments, a temperature of the thermal annealing ranges between 120° C.-140° C., such as 122° C., 125° C., 128° C., 130° C., 132° C., 135° C., 138° C., etc. A time of the thermal annealing ranges between 10 min-30 min, such as 12 min, 15 min, 18 min, 20 min, 22 min, 25 min, 28 min, etc.

Under the condition of the thermal annealing, the crosslinking of the fluorine-containing ester compound might be promoted to form a three-dimensional network structure, the compactness of the film 100 might be improved, the erosion of water might be prevented, and the solvent might also be evaporated.

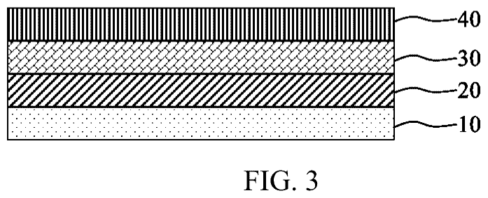

Referring to FIG. 3, the present disclosure discloses a photoelectric device, including:
a first electrode 10;
an active layer 30, located on the first electrode 10;
a second electrode 20, located on the active layer 30; and
a first carrier functional layer 20, between the first electrode 10 and the active layer 30, wherein the first carrier functional layer 20 includes the film 100 above-mentioned or the film 100 prepared by the preparation method above-mentioned.

A material of the film 100 could be referred to above, and will not be described here.

It should be noted that the photoelectric device provided by the present disclosure might be an upright photoelectric device or an inverted photoelectric device.

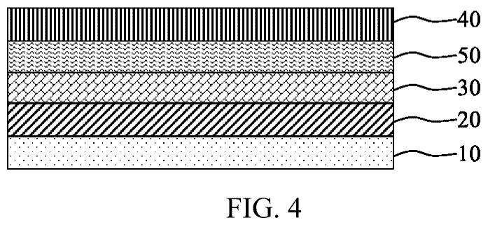

In some embodiments, referring to FIG. 4, the photoelectric device further includes a second carrier functional layer 50 disposed between the active layer 30 and the second electrode 40.

In some embodiments, the first carrier functional layer 20 is a hole functional layer, and the second carrier functional layer 50 is an electronic functional layer. A p-type semiconductor material in the first carrier functional layer 20 is a first p-type semiconductor material, and a material of the second carrier functional layer 50 is a second n-type semiconductor material. In other words, the first electrode 10 is an anode and the second electrode 40 is a cathode.

In other embodiments, the first carrier functional layer 20 is an electronic functional layer, and the second carrier functional layer 50 is a hole functional layer. A n-type semiconductor material in the first carrier functional layer is a first n-type semiconductor material, and a material of the second carrier functional layer 50 is a second p-type semiconductor material. In other words, the first electrode 10 is a cathode and the second electrode 40 is an anode.

The hole functional layer includes one or more of a hole injection layer and a hole transport layer.

The electronic functional layer includes one or more of an electronic injection layer and an electronic transport layer.

It should be noted that a material of the second carrier functional layer 50 may or may not include fluorine-containing ester compound. It could be understood that when both the first carrier functional layer 20 and the second carrier functional layer 50 include fluorine-containing ester compound, the corrosion of the active layer 30 caused by water passing through the carrier functional layer might be fully prevented.

In some embodiments, the second p-type semiconductor material is selected from one or more of 4,4′-N,N′-dicarbazolyl-biphenyl, N,N′-diphenyl-N,N′-bis(1-naphthyl)-1,1′-biphenyl)-4,4′-diamine, N,N′-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4,4′,4′-tris(carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris(N-3-methylphenyl-N-phenylamino)triphenylamine, poly[(9,9′-dioctyl fluorene-2,7-diyl)-co-(4,4′-(N-(4-sec-butylphenyl)diphenylamine))], poly(4-butylphenyl-diphenylamine), poly[bis(4-phenyl) (4-butylphenyl)amine], polyaniline, polypyrrole, poly(p)phenylene vinylene, poly(phenylene vinylene), poly[2-methoxy-5-(2-ethylhexyloxy)-1,4-phenylene vinylene], poly[2-methoxy-5-(3′,7′-dimethyl octyloxy)-1,4-phenylene vinylene], copper phthalocyanine, aromatic tertiary amine, 4,4′-bis(p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly(N-vinylcarbazole) and its derivatives, polymethacrylate and its derivatives, poly(9,9-octylfluorene) and its derivatives, poly(spirofluorene) and its derivatives, N,N′-bis(naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

In some embodiments, the second n-type semiconductor material is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, the film includes at least two film layers, and a mass fraction of the dopant in each film layer tends to increase or decrease in the same direction. In other words, the mass fraction of dopant in any adjacent film layer increases in the same direction in turn, forming gradient doping, which makes the energy level of the film layer change gradient and is beneficial to hole transport.

A material of the first electrode 10 and the second electrode 40 is each independently selected from one or more of metal, carbon material and metal oxide. The metal is selected from one or more of Al, Ag, Cu, Mo, Au, Ba, Ca, Yb and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/A/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, the active layer 30 includes a luminescent layer, a material of the luminescent layer is luminescent material, and the luminescent material is selected from one or more of organic luminescent material and quantum dot luminescent material.

A material of the organic luminescent material is selected from one or more of CBP:Ir(mppy)₃(4,4′-bis(N-carbazole)-1,1′-biphenyl:tris[2-(p-tolyl)pyridine iridium (III)]), TCTX:Ir(mmpy)(4,4′), 4″-tris(carbazole-9-yl)triphenylamine:tris[2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B—N covalent bonds, HLCT (hybrid local charge transfer excited state) materials and Exciplex luminescent materials.

The quantum dot luminescent material might be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot might be respectively selected from but not limited to one or more of second II-VI compound, second IV-VI compound, second III-V compound and I-III-VI compound. A shell layer of the core-shell structure quantum dot comprises one or more layers. The second II-VI compound is selected from one or more of CdS, CdSe, CdTe, ZnS. ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS. HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS. SnSe, SnTe, PbS, PbSe, PbTe, SnSeS, SnSeTe, SnSTe, PbSeS, PbSeTe, PbSTe, SnPbS. SnPbSe, SnPbTe, SnPbSSe, SnPbSeTe and SnPbSTe. The second III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GalnNP, GalnNAs, GalnNSb, GalnPAs, GalnPSb, InAINP, InAINAs, InAINSb, InAlPAs and InAlPSb. The I-III-VI compound is selected from one or more of CuInS₂, CuInSe, and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺. Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl. Br and I. The general structural formula of the organic-inorganic hybrid perovskite semiconductor is BMX₃, wherein B is an organic amine cation selected from CH₃(CH₂)ₙ₋₂NH₃⁺ or [NH₃ (CH₂),NH₃]²⁺, wherein n>2, and M is a divalent metal cation selected from Pb²⁺, Sn²⁺, Cu²⁺, Ni²⁺, Cd²⁺ and Cr³⁺, and X is a halogen anion selected from one or more of Cl. Br and I. When n=2, inorganic metal halide octahedron MX₆⁴⁻ is connected by the way of co-top, the metal cation M is located in the center of the halogen octahedron, and the organic amine cation B is filled in the gap between the octahedrons, forming an infinite three-dimensional structure. When n>2, inorganic metal halide octahedron MX₆⁴⁻ connected in a co-top manner extends in two-dimensional direction to form a layered structure, and an organic amine cationic bilayer (protonated monoamine) or an organic amine cationic monolayer (protonated diamine) is inserted between the layers, and the organic layer and the inorganic layer overlap each other to form a stable two-dimensional layered structure.

In some embodiments, the material of the active layer 30 further includes a second hydrophobic ligand connected to the luminescent material. The second hydrophobic ligand might prevent water from corroding the luminescent material.

In some embodiments, the second hydrophobic ligand includes substituted or unsubstituted hydrocarbon group.

In some embodiments, the hydrocarbon group includes one or more of chain hydrocarbon group and cyclic hydrocarbon group. The hydrocarbyl group includes one or more of alkyl group with 1-20 carbon atoms in the main chain, alkenyl group with 1-20 carbon atoms in the main chain and alkynyl group with 1-20 carbon atoms in the main chain. The cyclic hydrocarbon group includes one or more of aryl with 6-20 ring atoms and heteroaryl with 5-20 ring atoms.

In some embodiments, a substituent of the hydrocarbon group includes one or more of aryl, ester, ether, amine, amide and halogen.

In some embodiments, the second hydrophobic ligand is selected from one or more of methane, carbon tetrachloride, ethylene, polyvinyl fluoride and benzene.

In some embodiments, in the active layer 30, a mass ratio of the luminescent material to the second hydrophobic ligand is (90-99):(1-10), such as 91:9, 92:8, 93:7, 94:6, 95:5, 96:4, 97:3, etc. Within the mass ratio range, the second hydrophobic ligand might improve the water-oxygen corrosion resistance of the active layer 30.

The present disclosure also discloses a display device, including the photoelectric device in any of the above embodiments.

The display device might be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device might be a smart bracelet, smart glasses, and a smart watch.

This present disclosure will be explained in detail by specific examples. The following examples are only partial examples of this present disclosure, and are not limited to this present disclosure.

### Example 1

This example provides a film, and a preparation method of the film includes steps S1-S3.

In step S1, a substrate is provided.

In step S2, a mixed solution is provided, and the mixed solution includes ZnO nanoparticles and fluorinated polyurethane, wherein a mass ratio of ZnO to fluorinated polyurethane is 85:15.

In step S3, the mixed solution is spin-coated on the substrate and heated at 130° C. for 20 min to cross-link the fluorine-containing polyurethane, and a film with a thickness of 30 nm is obtained.

### Example 2

This example is basically the same as Example 1, only the difference is that in this example, ZnO is replaced by TiO₂.

### Example 3

This example is basically the same as Example 1, only the difference is that in this example, the fluorinated polyurethane is replaced by fluorinated acrylate.

### Example 4

This example is basically the same as Example 1, only the difference is that in this example, the fluorinated polyurethane is replaced by fluorinated cyanate ester.

### Example 5

This example is basically the same as Example 1, only the difference is that in this example, a mass ratio of ZnO to fluorinated polyurethane is 70:30.

### Example 6

This example is basically the same as Example 1, only the difference is that in this example, a mass ratio of ZnO to fluorinated polyurethane is 95:5.

### Example 7

This example is basically the same as Example 1, only the difference is that in this example, a surface of ZnO is further connected with hydrophobic ligand carbon tetrachloride, and a mass ratio of ZnO to the carbon tetrachloride and the fluorinated polyurethane is 75:10:15.

### Example 8

This example is basically the same as Example 1, only the difference is that in this example, the mixed solution further includes conductivity enhancer carbon black, and a mass ratio of ZnO to the carbon black and the fluorinated polyurethane is 82:3:15.

### Example 9

This example is basically the same as Example 1, only the difference is that in this example, a surface of ZnO is further connected with hydrophobic ligand benzene, and the mixed solution further includes conductivity enhancer Ag, and a mass ratio of ZnO to the benzene, Ag and the fluorinated polyurethane is 72:10:3:15.

### Example 10

This example is basically the same as Example 1, only the difference is that in this example, ZnO is replaced by NiO.

### Example 11

This example is basically the same as Example 10, only the difference is that in this example, a surface of NiO is further connected with hydrophobic ligand carbon tetrachloride, and a mass ratio of NiO to the carbon tetrachloride and the fluorinated polyurethane is 75:10:15.

### Example 12

This example is basically the same as Example 10, only the difference is that in this example, the mixed solution further includes conductivity enhancer carbon black, and a mass ratio of NiO to the carbon black and the fluorinated polyurethane is 82:3:15.

### Example 13

This example is basically the same as Example 10, only the difference is that in this example, a surface of NiO is further connected with hydrophobic ligand benzene, and the mixed solution further includes conductivity enhancer Ag, and a mass ratio of NiO to the benzene, Ag and the fluorinated polyurethane is 72:10:3:15.

### Comparative Example 1

This comparative example is basically the same as Example 1, only the difference is in this comparative example, the mixed solution does not include the fluorinated polyurethane.

### Comparative Example 2

This comparative example is basically the same as Example 1, only the difference is in this comparative example, the fluorinated polyurethane is replaced by polyurethane.

### Comparative Example 3

This comparative example is basically the same as Example 1, only the difference is in this comparative example, the fluorinated polyurethane is replaced by polytetrafluoroethylene.

### Comparative Example 4

This comparative example is basically the same as Example 10, only the difference is in this comparative example, the mixed solution does not include the fluorinated polyurethane. Performance test:

A surface roughness R_{q} and contact angle of the films of Examples 1-13 and Comparative Examples 1˜4 were tested respectively, and the results are shown in Table 1. The surface roughness is measured by AFM, and the contact angle is directly measured by contact angle meter.

TABLE 1

| | Surface roughness R_{q} | Contact angle |
|---|---|---|
| | (nm) | (°) |
| Example 1 | 2 | 60 |
| Example 2 | 2.2 | 58 |
| Example 3 | 2.1 | 59 |
| Example 4 | 2 | 61 |
| Example 5 | 3.6 | 50 |
| Example 6 | 1.5 | 65 |
| Example 7 | 2.1 | 60 |
| Example 8 | 2.2 | 30 |
| Example 9 | 2 | 60 |
| Example 10 | 2 | 60 |
| Example 11 | 2.1 | 60 |
| Example 12 | 2.2 | 51 |
| Example 13 | 2 | 60 |
| Comparative Example 1 | 5 | 30 |
| Comparative Example 2 | 4.5 | 38 |
| Comparative Example 3 | 4 | 45 |
| Comparative Example 4 | 4.2 | 30 |

It could be seen from Examples 1-4 and Comparative Examples 1-3 that fluorine-containing ester compounds were added to the films in Examples 1-4 provided by this present disclosure, which significantly reduced the surface roughness of the films and increased the contact angle compared with the comparative examples. The greater the contact angle, the better the hydrophobicity, and the less susceptible to water erosion. Comparative Examples 2-3 used fluorine-free resin and fluorine-containing olefin resin, which improved the water corrosion resistance of the film better than Comparative Example 1, but still worse than Examples 1-4. From Examples 1, 5˜6 and Comparative Example 1, it could be seen that the content of fluorine-containing ester compound will affect the surface roughness and hydrophobicity of the film to a certain extent. Within the range provided by this present disclosure, when more fluorine-containing ester compound are added, the performance improvement effect of the film is slightly worse than that of the film with less fluorine-containing ester, but they are all significantly better than that of Comparative Example 1.

From Examples 1, 7˜9 and Comparative Example 1, it could be seen that the contact angle of the films might be further improved by adding hydrophobic ligands to the film, that is, the hydrophobicity of the film might be improved and the film might be prevented from being corroded by water. Adding the conductivity enhancer has little effect on the surface roughness and contact angle of the film, on the one hand, it is because the addition content of the conductivity enhancer is small, and on the other hand, the main function of the conductivity enhancer is to increase the conductivity of the film.

From Examples 1, 10-13 and Comparative Example 4, there is little difference between p-type semiconductor material and n-type semiconductor material in the film, which might effectively reduce the surface roughness of the film, improve the compactness of the film and reduce the leakage current. Adding hydrophobic ligands to p-type semiconductor material might further improve the contact angle of the film and increase the water resistance of the film.

### Photoelectric Device Example 1

This example provides a photoelectric device, and a preparation method of the photoelectric device includes steps S21-S26.

In step S21, an ITO substrate is provided, the surface of ITO substrate is treated with ultraviolet ozone for 5 min to remove the organic matter attached to the surface of the ITO substrate and improve the work function of the ITO substrate to form anode.

In step S22, a solution of NiO is spin-coated on the ITO substrate, and then heated at 150° C. for 20 min to form a hole transport layer with a thickness of 40 nm.

In step S23, a quantum dot solution of CdZnS is provided, and then spin-coated on the hole transport layer to form a luminescent layer.

In step S24, the film is formed on the luminescent layer according to the method of Example 1 to prepare an electronic transport layer.

In step S25, Ag is thermally evaporated on the electronic transport layer by placing it in the evaporation bin and passing through the mask plate, and a cathode is formed.

In step S26, a photoelectric device is obtained after packaging.

### Photoelectric device Examples 2-9

Photoelectric device Examples 2-9 are basically the same as Photoelectric device Example 1, and only the difference is that films are separately formed on the luminescent layer according to the method of Examples 2-9 to prepare electronic transport layer.

### Photoelectric Device Examples 10

Photoelectric device Example 10 is basically the same as Photoelectric device Example 1, and only the difference is that film is formed on the luminescent layer according to the method of Comparative Example 1 to prepare electronic transport layer, and the hole transport layer is formed according to the method of Example 10.

### Photoelectric Device Examples 11

Photoelectric device Example 11 is basically the same as Photoelectric device Example 1, and only the difference is that film is formed on the luminescent layer according to the method of Comparative Example 1 to prepare electronic transport layer, and the hole transport layer is formed according to the method of Example 11.

### Photoelectric Device Examples 12

Photoelectric device Example 12 is basically the same as Photoelectric device Example 1, and only the difference is that film is formed on the luminescent layer according to the method of Comparative Example 1 to prepare electronic transport layer, and the hole transport layer is formed according to the method of Example 12.

### Photoelectric Device Examples 13

Photoelectric device Example 13 is basically the same as Photoelectric device Example 1, and only the difference is that film is formed on the luminescent layer according to the method of Comparative Example 1 to prepare electronic transport layer, and the hole transport layer is formed according to the method of Example 13.

### Photoelectric Device Examples 14

Photoelectric device Example 14 is basically the same as Photoelectric device Example 1, and only the difference is that the hole transport layer is formed according to the method of Example 10.

### Photoelectric Device Examples 15

Photoelectric device Example 15 is basically the same as Photoelectric device Example 9, and only the difference is that the hole transport layer is formed according to the method of Example 13.

### Photoelectric Device Examples 16

Photoelectric device Example 16 is basically the same as Photoelectric device Example 1, and only the difference is that a surface of CdZnS quantum dot is connected with hydrophobic ligand ethylene.

### Photoelectric Device Examples 17

Photoelectric device Example 17 is basically the same as Photoelectric device Example 15, and only the difference is that a surface of CdZnS quantum dot is connected with hydrophobic ligand ethylene.

### Photoelectric Device Comparative Examples 1-3

Photoelectric device Comparative Examples 1-3 are basically the same as photoelectric device Example 1, and only the difference is that films are separately formed on the luminescent layer according to the method of Comparative Examples 1-3 to prepare electronic transport layer.

### Performance Test:

Water resistance test of the photoelectric devices in Photoelectric device Examples 1-17 and Photoelectric device Comparative Examples 1-3 were tested respectively. The result obtained are shown in Table 2.

The water resistance test includes: the photoelectric devices in Photoelectric device Examples 1-17 and Photoelectric device Comparative Examples 1-3 were placed in an atmosphere with humidity of 60% for 10 min and taken out. The external quantum efficiency (EQE) and lifetime T95@1k nit of photoelectric devices before and after being placed in water were measured.

The external quantum efficiency (EQE) is an important parameter to measure the quality of electroluminescent devices, which could be measured by EQE optical testing instrument. The external quantum efficiency represents the ratio of the electron-hole logarithm injected into a quantum dot to the number of photons emitted, and the unit is %. The specific calculation formula is as follows:

$$EQE = η e η r χ \frac{{K}_{R}}{{K}_{R} + {K}_{NR}} .$$

Where ηe is the light output coupling efficiency, ηr is the ratio of the number of recombination carriers to the number of injected carriers, χ is the ratio of the number of excitons generating photons to the total number of excitons, KR is the radiation process rate, and K_{NR} is the non-radiation process rate. The test was carried out at room temperature, and the air humidity was 30%-60%.

When photoelectric device is driven by constant current, the time when the brightness drops to 95% of the highest brightness is defined as T95, which indicates the measured lifetime. In order to shorten the test period, the photoelectric device lifetime test is usually carried out by accelerating the aging of the photoelectric device under high brightness, and the lifetime under high brightness is obtained by fitting the extended exponential decay brightness attenuation formula, for example, the lifetime at 1000 nit is T95@1000 nit (T95@1k nit). The specific calculation formula is as follows:

$$T {95}_{L} = T {95}_{H} \cdot {( \frac{{L}_{H}}{{L}_{L}} )}^{A} .$$

Where T95_{L} is the lifetime under low brightness, T95_{H} is the measured lifetime under high brightness, L_{H} is the acceleration of the device to the highest brightness, L_{L} is 1000 nit, and A is the acceleration factor. In this experiment, the lifetime of several groups of QLED devices under rated brightness is measured and the value of A is 1.7.

TABLE 2

| | Before water resistance | | After water resistance | |
|---|---|---|---|---|
| | test | | test | |
| | EQE | T95@1k | EQE | T95@1k |
| | (%) | nit (h) | (%) | nit (h) |
| Photoelectric | 30 | 49999 | 28 | 47556 |
| device Example 1 | | | | |
| Photoelectric | 30 | 49558 | 27.5 | 47229 |
| device Example 2 | | | | |
| Photoelectric | 30 | 49887 | 28.6 | 48220 |
| device Example 3 | | | | |
| Photoelectric | 30 | 50120 | 28.1 | 48536 |
| device Example 4 | | | | |
| Photoelectric | 30 | 50001 | 21 | 30221 |
| device Example 5 | | | | |
| Photoelectric | 30 | 49494 | 19 | 27556 |
| device Example 6 | | | | |
| Photoelectric | 30 | 49458 | 27 | 46998 |
| device Example 7 | | | | |
| Photoelectric | 35 | 55441 | 20 | 45688 |
| device Example 8 | | | | |
| Photoelectric | 35 | 55446 | 31 | 50221 |
| device Example 9 | | | | |
| Photoelectric | 30 | 49665 | 28 | 47001 |
| device Example 10 | | | | |
| Photoelectric | 31 | 49752 | 29 | 47554 |
| device Example 11 | | | | |
| Photoelectric | 32 | 55664 | 29 | 50221 |
| device Example 12 | | | | |
| Photoelectric | 32 | 56441 | 30 | 50447 |
| device Example 13 | | | | |
| Photoelectric | 30 | 49887 | 29.6 | 49114 |
| device Example 14 | | | | |
| Photoelectric | 38 | 62887 | 37 | 60221 |
| device Example 15 | | | | |
| Photoelectric | 30 | 51221 | 29.8 | 50884 |
| device Example 16 | | | | |
| Photoelectric | 38 | 62554 | 37 | 61004 |
| device Example 17 | | | | |
| Photoelectric device | 25 | 48000 | 10 | 5000 |
| Comparative | | | | |
| Example 1 | | | | |
| Photoelectric device | 26 | 48550 | 15 | 20114 |
| Comparative | | | | |
| Example 2 | | | | |
| Photoelectric device | 27 | 49558 | 18 | 25446 |
| Comparative | | | | |
| Example 3 | | | | |

From Photoelectric device Examples 1-4 and Photoelectric device Comparative Examples 1-3, it could be seen that the external quantum efficiency and service life of photoelectric devices are significantly improved by applying fluorine-containing ester compound to the electronic transport layer before or after the water resistance test. Before the water resistance test, there was a certain improvement effect because fluorine-containing ester compound improved the compactness of the film and reduced the leakage current. The effect of water resistance test is very remarkable, because fluorine-containing ester compound form a cross-linked network, which not only prevents water from eroding the electronic transport layer, but also prevents water from eroding the luminescent layer through the electronic transport layer. Photoelectric device Comparative Examples 2-3 used fluorine-free resin and fluorine-containing olefin resin. Compared with the photoelectric device of Photoelectric device Comparative Example 1, the external quantum efficiency and service life were improved to some extent, but after the water resistance test, its performance dropped sharply, which was still worse than that of Photoelectric device Examples 1-4.

From Photoelectric device Examples 1, 5-6 and the Photoelectric device Comparative Example 1, it could be seen that the content of fluorine-containing ester compound has no obvious influence on the performance of photoelectric devices within the range provided by this present disclosure, and the performance of photoelectric devices is relatively better when fluorine-containing ester compound is properly added within the range provided by this present disclosure (Photoelectric device Example 1). It could be understood that the content of fluorine-containing ester compound in Photoelectric device Example 6 is relatively small, so its performance after water resistance test is slightly worse than that in Photoelectric device Example 1 and Photoelectric device Example 5.

From Photoelectric device Examples 1, 7-9 and Photoelectric device Comparative Example 1, it could be seen that adding conductivity enhancer into the film might promote the injection and transmission of electrons, and further improve the external quantum efficiency and service life of photoelectric devices. After the water resistance test, Photoelectric device Examples 7-9 still maintain high external quantum efficiency and service life.

From Photoelectric device Examples 10-15 and Photoelectric device Comparative Example 1, it could be seen that the external quantum efficiency and water resistance of photoelectric devices might be effectively improved by adding fluorine-containing ester compound to both hole transport layer and electronic transport layer.

From Photoelectric device Examples 1, 16-17 and Photoelectric device Comparative 1, it could be seen that the water resistance of photovoltaic devices might also be improved by further adding hydrophobic ligands in the light-emitting layer, thus improving the external quantum efficiency of photovoltaic devices and prolonging the service life of photovoltaic devices.

Film, preparation method thereof and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A film, wherein a material of the film comprises a semiconductor material and a fluorine-containing ester compound.

2. The film according to claim 1, wherein a mass ratio of the semiconductor material to the fluorine-containing ester compound is (45-95):(5-30); and
the fluorine-containing ester compound has a three-dimensional network cross-linked structure, and the semiconductor material is filled in the three-dimensional network cross-linked structure.

3. The film according to claim 1, wherein the fluorine-containing ester compound comprises one or more of fluorine-containing amino ester compound, fluorine-containing acid ester compound and fluorine-containing hydrocarbon ester compound; and
the semiconductor material comprises one or more of p-type semiconductor material and n-type semiconductor material.

4. The film according to claim 3, wherein the fluorine-containing amino ester compound comprises fluorinated polyurethane; the fluorine-containing acid ester compound comprises one or more of fluorinated acrylate, and fluorinated cyanate ester; and the fluorine-containing hydrocarbon ester compound comprises one or more of fluorine-containing vinyl ester compound.

5. The film according to claim 3, wherein the n-type semiconductor material is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS; and
the p-type semiconductor material is selected from one or more of 4,4′-N,N′-dicarbazolyl-biphenyl, N,N′-diphenyl-N,N′-bis(1-naphthyl)-1,1′-biphenyl)-4,4 ‘-diamine, N,N’-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4,4′,4′-tris(carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris(N-3-methylphenyl-N-phenylamino)triphenylamine, poly[(9,9′-dioctyl fluorene-2,7-diyl)-co-(4,4′-(N-(4-sec-butylphenyl)diphenylamine))], poly(4-butylphenyl-diphenylamine), poly[bis(4-phenyl) (4-butylphenyl)amine], polyaniline, polypyrrole, poly(p)phenylene vinylene, poly(phenylene vinylene), poly[2-methoxy-5-(2-ethylhexyloxy)-1,4-phenylene vinylene], poly[2-methoxy-5-(3′,7′-dimethyl octyloxy)-1,4-phenylene vinylene], copper phthalocyanine, aromatic tertiary amine, 4,4′-bis(p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly(N-vinylcarbazole) and its derivatives, polymethacrylate and its derivatives, poly(9,9-octylfluorene) and its derivatives, poly(spirofluorene) and its derivatives, N,N′-bis(naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

6. The film according to claim 1, wherein a surface of the semiconductor material is connected with a first hydrophobic ligand; and
the material of the film further comprises a conductivity enhancer.

7. The film according to claim 6, wherein the first hydrophobic ligand comprises substituted or unsubstituted hydrocarbon group; the hydrocarbon group comprises one or more of chain hydrocarbon group and cyclic hydrocarbon group; the hydrocarbyl group comprises one or more of alkyl group with 1-20 carbon atoms in the main chain, alkenyl group with 1-20 carbon atoms in the main chain and alkynyl group with 1-20 carbon atoms in the main chain, and the cyclic hydrocarbon group comprises one or more of aryl with 6-20 ring atoms and heteroaryl with 5-20 ring atoms; a substituent of the hydrocarbon group comprises one or more of aryl, ester, ether, amine, amide and halogen; and the first hydrophobic ligand is selected from one or more of methane, carbon tetrachloride, ethylene, polyvinyl fluoride and benzene; and
a mass ratio of the semiconductor material to the first hydrophobic ligand is (45-95):(1-20).

8. The film according to claim 6, wherein a conductivity of the conductivity enhancer ranges between 100S/m-500S/m;
a mass ratio of the semiconductor material to the conductivity enhancer in the film is (45-95):(1-5); and
the conductivity enhancer is selected from one or more of carbon material and metal material; the carbon material is selected from one or more of carbon black, conductive graphite, cochin black and carbon nanotube; and the metal material is selected from one or more of Au, Cu, Ag, Al and Fe.

9. A preparation method of a film, comprising:
providing a mixed solution, the mixed solution comprises a semiconductor material and a fluorine-containing ester compound; and
deposing the mixed solution to obtain the film.

10. The preparation method according to claim 9, wherein a mass ratio of the semiconductor material to the fluorine-containing ester compound is (45-95):(5-30);
a mass concentration of the semiconductor material in the mixed solution ranges between 10 mg/mL-30 mg/mL;
the fluorine-containing ester compound comprises one or more of fluorine-containing amino ester compound, fluorine-containing acid ester compound and fluorine-containing hydrocarbon ester compound; the fluorine-containing amino ester compound comprises fluorinated polyurethane; the fluorine-containing acid ester compound comprises one or more of fluorinated acrylate, and fluorinated cyanate ester; and the fluorine-containing hydrocarbon ester compound comprises one or more of fluorine-containing vinyl ester compound; and
the semiconductor material comprises one or more of p-type semiconductor material and n-type semiconductor material.

11. The preparation method according to claim 9, wherein the mixed solution further comprises a solvent; and the solvent comprises an alcohol solvent, and the alcohol solvent is selected from one or more of 3-methoxybutan-1-ol, methanol, ethanol, propanol, butanol, ethylene glycol, isopropanol, glycerol and cresol.

12. The preparation method according to claim 9, wherein the mixed solution further comprises a first hydrophobic ligand;
wherein the first hydrophobic ligand comprises substituted or unsubstituted hydrocarbon group; the hydrocarbon group comprises one or more of chain hydrocarbon group and cyclic hydrocarbon group; the hydrocarbyl group comprises one or more of alkyl group with 1-20 carbon atoms in the main chain, alkenyl group with 1-20 carbon atoms in the main chain and alkynyl group with 1-20 carbon atoms in the main chain, and the cyclic hydrocarbon group comprises one or more of aryl with 6-20 ring atoms and heteroaryl with 5-20 ring atoms; a substituent of the hydrocarbon group comprises one or more of aryl, ester, ether, amine, amide and halogen; and the first hydrophobic ligand is selected from one or more of methane, carbon tetrachloride, ethylene, polyvinyl fluoride and benzene; and
a mass ratio of the semiconductor material to the first hydrophobic ligand is (45-95):(1-20).

13. The preparation method according to claim 9, wherein the mixed solution further comprises a conductivity enhancer;
wherein a conductivity of the conductivity enhancer ranges between 100S/m-500S/m;
a mass ratio of the semiconductor material to the conductivity enhancer in the mixed solution is (45-95):(1-5); and
the conductivity enhancer is selected from one or more of carbon material and metal material; the carbon material is selected from one or more of carbon black, conductive graphite, cochin black and carbon nanotube; and the metal material is selected from one or more of Au, Cu, Ag, Al and Fe.

14. The preparation method according to claim 9, wherein after disposing the mixed solution, the method further comprises thermal annealing; and a temperature of the thermal annealing ranges between 120° C.-140° C., and a time of the thermal annealing ranges between 10 min-30 min.

15. A photoelectric device, comprising:
a first electrode;
an active layer, located on the first electrode;
a second electrode, located on the active layer; and
a first carrier functional layer, between the first electrode and the active layer, and a material of the first carrier functional layer comprises a semiconductor material and a fluorine-containing ester compound.

16. The photoelectric device according to claim 15, wherein the fluorine-containing ester compound comprises one or more of fluorine-containing amino ester compound, fluorine-containing acid ester compound and fluorine-containing hydrocarbon ester compound; the fluorine-containing amino ester compound comprises fluorinated polyurethane; the fluorine-containing acid ester compound comprises one or more of fluorinated acrylate, and fluorinated cyanate ester; and the fluorine-containing hydrocarbon ester compound comprises one or more of fluorine-containing vinyl ester compound; and
the semiconductor material comprises one or more of p-type semiconductor material and n-type semiconductor material.

17. The photoelectric device according to claim 16, wherein further comprises a second carrier functional layer disposed between the active layer and the second electrode;
the first carrier functional layer is a hole functional layer, and the second carrier functional layer is an electronic functional layer; the p-type semiconductor material in the first carrier functional layer is a first p-type semiconductor material, and a material of the second carrier functional layer is a second n-type semiconductor material; or
the first carrier functional layer is an electronic functional layer, and the second carrier functional layer is a hole functional layer; the n-type semiconductor material in the first carrier functional layer is a first n-type semiconductor material, and a material of the second carrier functional layer is a second p-type semiconductor material.

18. The photoelectric device according to claim 17, wherein a material of the first electrode and the second electrode is each independently selected from one or more of metal, carbon material and metal oxide, and the metal is selected from one or more of Al, Ag, Cu, Mo, Au, Ba, Ca, Yb and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO, and the composite electrode is selected from one or more of AZO/Ag/AZO, AZO/AVAZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/AVTIO₂;
the second n-type semiconductor material is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and AL₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS;
the second p-type semiconductor material is selected from one or more of 4,4′-N,N′-dicarbazolyl-biphenyl, N,N′-diphenyl-N,N′-bis(1-naphthyl)-1,1′-biphenyl)-4,4 ‘-diamine, N,N’-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4,4′,4′-tris(carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4.4′,4′-tris(N-3-methylphenyl-N-phenylamino)triphenylamine, poly[(9,9′-dioctyl fluorene-2,7-diyl)-co-(4,4′-(N-(4-sec-butylphenyl)diphenylamine))], poly(4-butylphenyl-diphenylamine), poly[bis(4-phenyl) (4-butylphenyl)amine], polyaniline, polypyrrole, poly(p)phenylene vinylene, poly(phenylene vinylene), poly[2-methoxy-5-(2-ethylhexyloxy)-1.4-phenylene vinylene], poly[2-methoxy-5-(3′,7′-dimethyl octyloxy)-1,4-phenylene vinylene], copper phthalocyanine, aromatic tertiary amine, 4,4′-bis(p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly(N-vinylcarbazole) and its derivatives, polymethacrylate and its derivatives, poly(9,9-octylfluorene) and its derivatives, poly(spirofluorene) and its derivatives, N,N′-bis(naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride; and
a material of the active layer is luminescent material, and the luminescent material is selected from one or more of organic luminescent material and quantum dot luminescent material; and a material of the organic luminescent material is selected from one or more of CBP:Ir(mppy)₃, TCTX:Ir (mmpy), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF materials, polymers containing B—N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot are respectively selected from but not limited to one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GalnNP, GalnNAs, GalnNSb, GalnPAs, GalnPSb, InAINP, InAINAs, InAINSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl, Br and I; the general structural formula of the organic-inorganic hybrid perovskite semiconductor is BMX₃, wherein B is an organic amine cation selected from CH₃ (CH₂)ₙ₋₂NH₃⁺ or [NH₃ (CH₂)ₙNH₃]2⁺, wherein n>2, and M is a divalent metal cation selected from Pb²⁺, Sn²⁺, Cu²⁺, Ni²⁺, Cd²⁺ and Cr³⁺, and X is a halogen anion selected from one or more of Cl, Br and I.

19. The photoelectric device according to claim 18, wherein the material of the active layer further comprises a second hydrophobic ligand connected to the luminescent material.

20. The photoelectric device according to claim 19, wherein the second hydrophobic ligand comprises substituted or unsubstituted hydrocarbon group; the hydrocarbon group comprises one or more of chain hydrocarbon group and cyclic hydrocarbon group; the hydrocarbyl group comprises one or more of alkyl group with 1-20 carbon atoms in the main chain, alkenyl group with 1-20 carbon atoms in the main chain and alkynyl group with 1-20 carbon atoms in the main chain, and the cyclic hydrocarbon group comprises one or more of aryl with 6-20 ring atoms and heteroaryl with 5-20 ring atoms; a substituent of the hydrocarbon group comprises one or more of aryl, ester, ether, amine, amide and halogen; and the second hydrophobic ligand is selected from one or more of methane, carbon tetrachloride, ethylene, polyvinyl fluoride and benzene; and
a mass ratio of the luminescent material to the second hydrophobic ligand is (90-99):(1-10).
